(19) United States
(12) Patent Application Publication
(10) Pub. No.: US 2026/0185221 A1
(43) Pub. Date: Jul. 2, 2026

(54) SUBSTRATE DEPOSITION APPARATUS AND METHOD

(71) Applicant: Samsung Electronics Co., Ltd., Suwon-si (KR)

(72) Inventors: WOOHYUN KIM, Suwon-si (KR); WOO-HEE KIM, Ansan-si (KR); MINGEON KIM, Suwon-si (KR); SENA KIM, Suwon-si (KR); JEONG-MIN LEE, Ansan-si (KR); JOONMYEONG CHOI, Suwon-si (KR); WONSUB Hwang, Suwon-si (KR)

(73) Assignees: Samsung Electronics Co., Ltd., Suwon-si (KR); Industry-University Cooperation Foundation Hanyang University ERICA Campus, Ansan-si (KR)

(21) Appl. No.: 19/415,918

(22) Filed: Dec. 11, 2025

(30) Foreign Application Priority Data
Dec. 30, 2024 (KR) 10-2024-0201101

(51) Int. Cl. C23C 16/448; C23C 16/44; C23C 16/455; C23C 16/52

(52) U.S. Cl. CPC C23C 16/4486; C23C 16/4408; C23C 16/45544; C23C 16/45561; C23C 16/52

(57) ABSTRACT

A substrate deposition apparatus includes: a canister configured to discharge a precursor through a first supply line; a vaporizer comprising a frame connected to the first supply line, a first atomization device configured to spray atomizing gas to the precursor, a second atomization device configured to apply an external force to the precursor, and a heating device configured to heat the precursor; and a controller configured to control the second atomization device to switch between a high energy mode and a low energy mode, wherein an external force applied by the second atomization device to the precursor when the second atomization device is in the low energy mode is less than an external force applied by the second atomization device to the precursor when the second atomization device is in the high energy mode.

### CROSS-REFERENCE TO RELATED APPLICATION

This application is based on and claims priority under 35 U.S.C. § 119 to Korean Patent Application No. 10-2024-0201101, filed on Dec. 30, 2024, in the Korean Intellectual Property Office, the disclosure of which is incorporated by reference herein in its entirety.

### BACKGROUND

The inventive concept relates to substrate deposition apparatuses, and more particularly, to a substrate deposition apparatus including a vaporizer.

As semiconductor chips become more highly integrated, an atomic layer deposition (ALD) process becomes very important. In the ALD process, precursors are used to sequentially cause chemical reactions on a deposition surface, and thus a thin film may be formed with a uniform thickness on the deposition surface. However, in the ALD process, thin films are deposited layer by layer, so a deposition speed is relatively slow. Research is ongoing to shorten the deposition process time while maintaining advantages of the ALD process.

### SUMMARY

Aspects of the inventive concept provide a substrate deposition apparatus that performs an atomic layer deposition process and a chemical vapor deposition process.

However, the technical problems to be achieved in this document are not limited to the above-mentioned technical problems, and other technical problems not mentioned will be clearly understood by a person skilled in the art to which the disclosure pertains from the following description.

According to an aspect of the inventive concept, a substrate deposition apparatus is configured to perform a deposition process on a substrate, and includes a canister configured to discharge a precursor through a first supply line, a vaporizer comprising a frame connected to the first supply line of the canister, a first atomization device configured to spray atomizing gas to the precursor introduced into an internal space of the frame, a second atomization device configured to apply an external force to the precursor introduced into the internal space of the frame, and a heating device configured to heat the precursor introduced into the internal space of the frame, and a controller configured to control the second atomization device to switch between a high energy mode and a low energy mode in which different external forces are applied to the precursor introduced into the internal space of the frame, while performing the deposition process. An external force applied by the second atomization device to the precursor when the second atomization device is in the low energy mode is less than an external force applied by the second atomization device to the precursor when the second atomization device is in the high energy mode.

According to another aspect of the inventive concept, a substrate deposition apparatus is configured to perform a deposition process on a substrate, the deposition process comprising a first sub-cycle and a second sub-cycle performed after the first sub-cycle. The substrate deposition apparatus includes a process chamber configured to receive the substrate for mounting in the process chamber; a precursor supply unit configured to supply a precursor to the process chamber; a reactant supply unit configured to supply a reactant to the process chamber; a purge supply unit configured to supply a purge gas to the process chamber; and a controller configured to control a supply amount of the precursor of the precursor supply unit, a supply amount of the reactant of the reactant supply unit, and a supply amount of the purge gas of the purge supply unit. The precursor supply unit comprises a canister configured to discharge the precursor through a first supply line; and a vaporizer comprising a frame connected to the first supply line of the canister, a first atomization device configured to spray atomizing gas to the precursor introduced into an internal space of the frame, a second atomization device configured to apply an external force to the precursor introduced into the internal space of the frame, and a heating device configured to heat the precursor introduced into the internal space of the frame. The controller is configured to control the second atomization device between a high energy mode and a low energy mode in which different external forces are applied to the precursor introduced into the internal space of the frame by the second atomization device, while performing the deposition process. An external force applied by the second atomization device to the precursor when the second atomization device is in the low energy mode is less than an external force applied by the second atomization device to the precursor when the second atomization device is in the high energy mode.

According to another aspect of the inventive concept, a substrate deposition apparatus is configured to perform a deposition process on a substrate, and includes a process chamber configured to receive a substrate for mounting in the process chamber; a precursor supply unit configured to supply a precursor to the process chamber; a reactant supply unit configured to supply a reactant to the process chamber; a purge supply unit configured to supply a purge gas to the process chamber; and a controller configured to control a supply amount of the precursor of the precursor supply unit, a supply amount of the reactant of the reactant supply unit, and a supply amount of the purge gas of the purge supply unit. The precursor supply unit comprises a canister configured to discharge the precursor in a liquid state to the outside through a first supply line; and a vaporizer comprising a frame connected to the first supply line of the canister, a first atomization device configured to spray atomizing gas to the precursor introduced into an internal space of the frame, a second atomization device comprising an ultrasonic generator for applying ultrasonic waves to the precursor introduced into the internal space of the frame, and a heating device configured to heat the precursor introduced into the internal space of the frame. The second atomization device comprises a low energy mode in which a frequency of ultrasonic waves generated by the ultrasonic generator is a first frequency and a high energy mode in which the frequency of the ultrasonic waves is a second frequency that is greater than the first frequency. The controller is configured to switch the second atomization device between the low energy mode and the high energy mode while performing the deposition process.

According to another aspect of the inventive concept, a method for depositing a material layer on a substrate includes vaporizing a precursor by spraying atomizing gas to the precursor while a first external force is applied to the precursor during a first deposition sub-cycle to result in a first vaporized precursor; introducing the first vaporized precursor to a chamber in which the substrate is disposed during the first deposition sub-cycle; vaporizing the precursor by spraying the atomizing gas to the precursor while a second external force is applied to the precursor during a second deposition sub-cycle that follows the first deposition sub-cycle to result in a second vaporized precursor; and introducing the second vaporized precursor to the chamber in which the substrate remains disposed during the second deposition sub-cycle. The first external force is greater than the second external force.

According to another aspect of the inventive concept, a method for depositing a material layer on a substrate includes placing the substrate in a chamber; performing an atomic layer deposition (ALD) process by alternately first supplying a precursor with a source gas to the chamber while not supplying a reactant to the chamber and second supplying the reactant to the chamber while not supplying the precursor or source gas; and subsequent to performing the ALD and without removing the substrate from the chamber, performing a chemical vapor deposition (CVD) process by third supplying the precursor with the source gas to the chamber while simultaneously supplying the reactant to the chamber. The combined ALD process and CVD process results in depositing the material layer on the substrate.

### BRIEF DESCRIPTION OF THE DRAWINGS

Embodiments will be more clearly understood from the following detailed description taken in conjunction with the accompanying drawings in which:

FIG. 1 is a diagram schematically illustrating a substrate deposition apparatus according to an embodiment;

FIG. 2 is a lateral cross-sectional view schematically illustrating a canister of a substrate deposition apparatus according to an embodiment;

FIG. 3 is a diagram schematically illustrating a portion of a substrate deposition apparatus according to an embodiment;

FIG. 4 is graphs showing respective supply amounts of materials and an external force that are provided during a deposition process of a substrate deposition apparatus according to an embodiment;

FIG. 5 is a graph showing an external force provided through a second atomization device during a deposition process of a substrate deposition apparatus according to an embodiment;

FIG. 6 is a graph showing a supply amount of a precursor provided through a canister during a deposition process of a substrate deposition apparatus according to an embodiment; and

FIGS. 7A, 7B, 8 through 10, 11A, 11B, and 12 are diagrams sequentially illustrating steps in which a substrate deposition apparatus performs a deposition process, according to an embodiment.

FIG. 13 is a flowchart showing the process depicted in FIGS. 4 through 6 as part of a method of manufacturing a semiconductor device, according to an embodiment.

### DETAILED DESCRIPTION OF THE EMBODIMENTS

The inventive concept may, however, be embodied in many different forms and should not be construed as being limited to the embodiments set forth herein; rather, these embodiments are provided so that this disclosure will be thorough and complete, and will fully convey the inventive concept to one of ordinary skill in the art.

It will be understood that, although the terms “first”, “second”, “third”, etc., may be used herein to describe various elements, components, regions, layers and/or sections, these elements, components, regions, layers and/or sections should not be limited by these terms. Unless the context clearly indicates otherwise, these terms are only used to distinguish one element, component, region, layer or section from another region, layer or section. Thus, a first element, component, region, layer or section discussed in one section could be termed a second element, component, region, layer or section in another section or the claims without departing from the teachings of the inventive concept. In addition, in certain cases, even when the specification does not describe elements with the terms “first”, “second”, etc., they may be referred to as “first” or “second” to distinguish them from each other in the claims.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

As is traditional in the field of the disclosed technology, some features and embodiments are described, and illustrated in the drawings, in terms of functional blocks, units, and/or modules. Those skilled in the art will appreciate that these blocks, units, and/or modules are physically implemented by physical components discussed in this specification, in addition to electronic (or optical) circuits such as logic circuits, discrete components, microprocessors, hard-wired circuits, memory elements, wiring connections, actuators, and the like, many of which may be formed using semiconductor-based fabrication techniques or other manufacturing technologies. In the case of the blocks, units, and/or modules such as a controller being implemented by microprocessors or similar, they may be programmed using software (e.g., microcode) to perform various functions discussed herein and may optionally be driven by firmware and/or software. Alternatively, each block, unit, and/or module may be implemented by dedicated hardware, or as a combination of dedicated hardware to perform some functions and a processor (e.g., one or more programmed microprocessors and associated circuitry) to perform other functions.

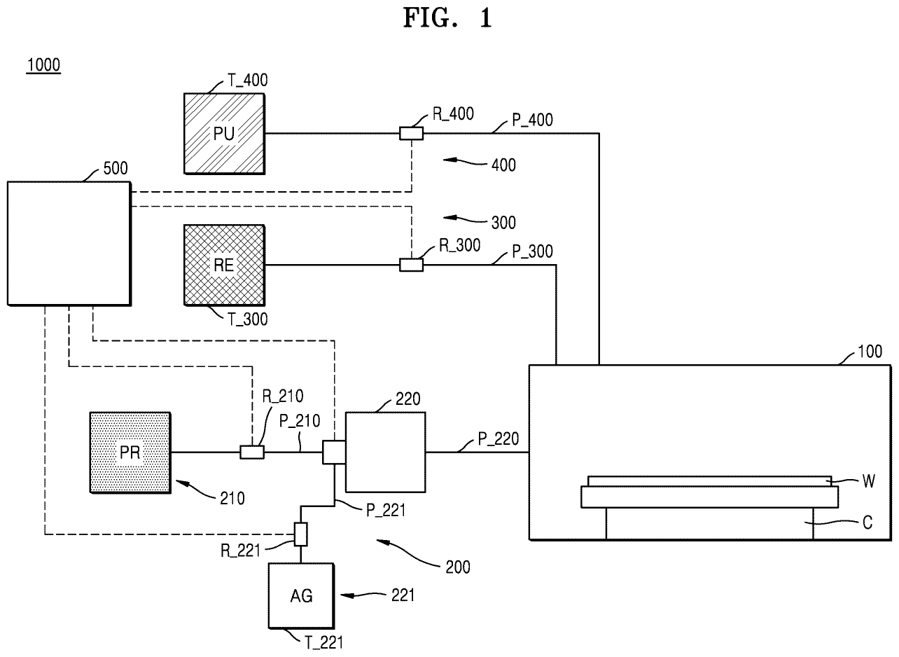

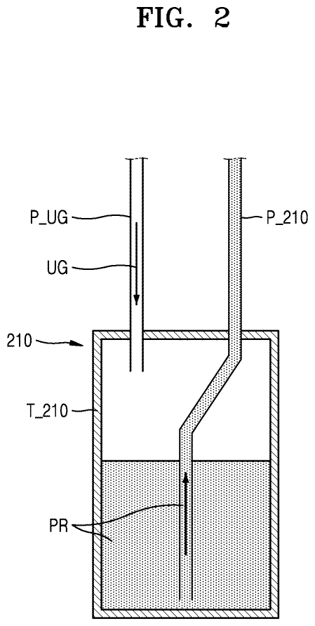

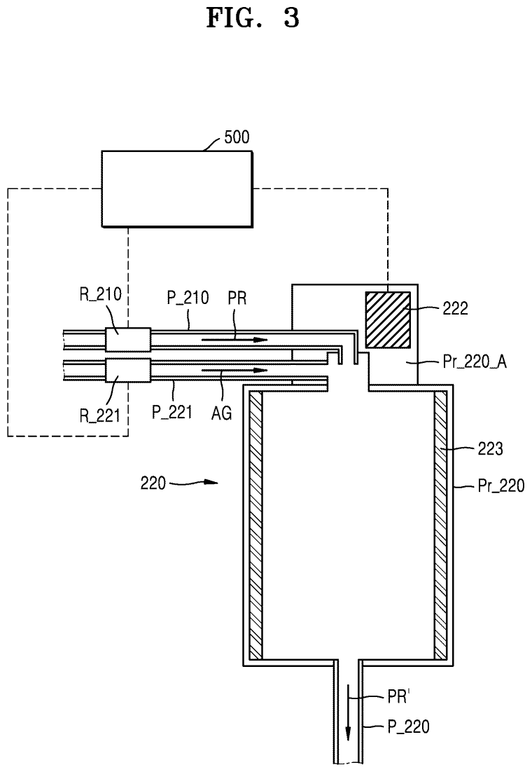

FIG. 1 is a diagram schematically illustrating a substrate deposition apparatus 1000 according to an embodiment. FIG. 2 is a lateral cross-sectional view schematically illustrating a canister 210 of the substrate deposition apparatus 1000 according to an embodiment. FIG. 3 is a diagram schematically illustrating a portion of the substrate deposition apparatus 1000 according to an embodiment.

Referring to FIGS. 1 through 3, the substrate deposition apparatus 1000 may comprise a process chamber 100, a precursor supply unit 200, a reactant supply unit 300, a purge supply unit 400, and a controller 500. The substrate deposition apparatus 1000 may perform a deposition process of depositing a thin film on a deposition surface of a substrate W placed in the process chamber 100.

The process chamber 100 may provide, therein, a processing space in which a process of the substrate W, which is a process target, is performed. For example, the process chamber 100 may have a cylindrical shape in which a processing space is formed. For example, the processing space may be sealed from the outside of the process chamber 100 by the inner wall of the process chamber 100.

Although not particularly illustrated and described, the process chamber 100 may comprise an exhaust hole in its bottom. The exhaust hole may be connected to an exhaust line equipped with a pump. The exhaust hole may discharge reaction byproducts generated during the deposition process and gases remaining inside the process chamber 100 to the outside of the process chamber 100 through the exhaust line. In this case, an internal space of the process chamber 100 may be depressurized to a preset pressure.

A substrate support C may be located inside the process chamber 100. For example, the substrate support C may be provided inside the processing space of the process chamber 100. The substrate support C may be configured to support the substrate W, which is a process substrate. For example, the substrate support C may support the substrate W such that an upper surface of the substrate W, i.e., the deposition surface of the substrate W, faces the ceiling of the process chamber 100 and a lower surface of the substrate W faces the bottom of the process chamber 100.

In some embodiments, the substrate support C may have a shape corresponding to the substrate W, for example, a disk shape. The substrate support C may be formed of, for example, a metal material or a ceramic material. According to some embodiments, the substrate support C may be an electrostatic chuck that supports a substrate with an electrostatic force or a vacuum chuck that supports a substrate with a negative pressure.

According to some embodiments, the substrate support C may comprise a lower structure having a first diameter and an upper structure having a second diameter that is greater than the first diameter and positioned on the lower structure. However, this is a distinction for convenience of explanation, and the lower structure and the upper structure may constitute the substrate support C, which is an integrated structure.

A support pin (not shown) may be positioned on the upper structure of the substrate support C. The substrate support C may support the substrate W through the support pin that contacts the lower surface of the substrate W. According to some embodiments, the second diameter of the upper structure of the substrate support C may be less than the diameter of the substrate W.

According to some embodiments, a plasma generation device may be located on the ceiling of the process chamber 100. The plasma generation device may generate microwaves in the processing space of the process chamber 100, and the microwaves may be used in the deposition process of the substrate deposition apparatus 1000.

The precursor supply unit 200 may comprise the canister 210 configured to store and provide a precursor PR, and a vaporizer 220 configured to vaporize the precursor PR.

Referring to FIG. 2, the canister 210 may comprise a precursor tank T_210 and a first supply line P_210. The precursor tank T_210 may provide a space for storing the precursor PR that is to be provided to the process chamber 100. For example, the precursor PR may be stored in the internal space of the precursor tank T_210.

According to some embodiments, the precursor PR may comprise tetra ethyl ortho silicate (SiOCH), silane, titanium chloride (TiCl), or aluminum chloride (AlCl). The precursor PR may comprise trimethylaluminum (TMA) (chemical formula AlCH), hafnium chloride (HfCl), and zirconium chloride (ZrCl).

The first supply line P_210 may be connected to the precursor tank T_210, and may provide a path along which the precursor PR stored in the precursor tank T_210 moves to the outside of the precursor tank T_210. For example, one end of the first supply line P_210 may be adjacent to the bottom of the precursor tank T_210. For example, the one end of the first supply line P_210 may be located within the precursor PR stored in the precursor tank T_210. The precursor PR may be introduced into the interior of the first supply line P_210 through the one end of the first supply line P_210 serving as an inlet.

According to some embodiments, the canister 210 may provide the precursor PR in a liquid state to the outside. For example, the first supply line P_210 of the canister 210 may be located inside the precursor PR stored in the precursor tank T_210 so that the precursor PR in a liquid state may be provided to the outside through the first supply line P_210. For example, the canister 210 may be a direct liquid injection (DLI) canister.

According to some embodiments, the canister 210 may further comprise a gas line P_UG, which is a path for pressurized gas UG that is injected into the precursor tank T_210. For example, the gas line P_UG may be connected to the ceiling of the precursor tank T_210, and thus one end of the gas line P_UG may be located above the precursor PR stored in the precursor tank T_210. For example, the one end of the gas line P_UG may be located outside the precursor PR stored in the precursor tank T_210.

For example, the pressurized gas UG injected into the precursor tank T_210 through the gas line P_UG may increase the pressure in the internal space of the precursor tank T_210. Accordingly, pressure applied to the surface of the precursor PR stored in the precursor tank T_210 increases so that the precursor PR stored in the precursor tank T_210 may be discharged to the outside along the first supply line P_210.

According to some embodiments, the pressurized gas UG may be gas that is lowly reactive with the precursor PR. For example, the pressurized gas UG may be an inert gas. For example, the pressurized gas UG may comprise argon (Ar), nitrogen (N), carbon dioxide (CO), and helium (He).

Referring back to FIG. 1, according to some embodiments, the precursor supply unit 200 may further comprise a first flow regulator R_210 provided on the first supply line P_210. The first flow regulator R_210 may regulate a flow rate of the precursor PR passing through the first supply line P_210. For example, a supply amount of the precursor PR flowing from the precursor tank T_210 to the vaporizer 220 may be controlled through the first flow regulator R_210. Accordingly, a supply amount of the precursor PR flowing from the precursor supply unit 200 to the process chamber 100 may be regulated through the first flow regulator R_210.

For example, a supply amount of the precursor PR supplied from the canister 210 to the vaporizer 220 may be the same as the supply amount of the precursor PR supplied from the precursor supply unit 200 to the process chamber 100. The supply amount of the precursor PR supplied from the canister 210 to the vaporizer 220 may refer to the supply amount of the precursor PR supplied from the precursor supply unit 200 to the process chamber 100.

For example, the first flow regulator R_210 may comprise a ball valve, a globe valve, a gate valve, a diaphragm valve, an electronic pressure regulator, and a solenoid valve.

According to some embodiments, the first flow regulator R_210 may include a small-volume supply mode and a large-volume supply mode in which the supply amounts of the precursor PR are different. For example, when the first flow regulator R_210 is in the small-volume supply mode, the canister 210 may supply the precursor PR to the vaporizer 220 at a first flow rate. When the first flow regulator R_210 is in the large-volume supply mode, the canister 210 may supply the precursor PR to the vaporizer 220 at a second flow rate that is greater than the first flow rate.

Referring to FIGS. 1 and 3, the vaporizer 220 may comprise a frame Pr_220, a first atomization device 221, a second atomization device 222, and a heating device 223.

The frame Pr_220 may provide an internal space in which the precursor PR introduced into the vaporizer 220 is vaporized. According to some embodiments, the frame Pr_220 may comprise an inflow portion Pr_220_A. For example, a portion of the frame Pr_220 to which the first supply line P_210 of the canister 210 is connected may be referred to as an inflow portion Pr_220_A of the frame Pr_220. For example, the inflow portion Pr_220_A of the frame Pr_220 may be a portion protruding from an upper wall of the frame Pr_220.

The first atomization device 221 may be located outside the frame Pr_220 of the vaporizer 220. The first atomization device 221 may be configured to spray atomizing gas AG onto the precursor PR introduced into the frame Pr_220 of the vaporizer 220.

The first atomization device 221 may comprise an atomizing gas tank T_221 in which the atomizing gas AG is stored, a second supply line P_221 providing a movement path for the atomizing gas AG, and a second flow regulator R_221 provided on the second supply line P_221.

For example, the second supply line P_221 may connect the atomizing gas tank T_221 to the frame Pr_220 of the vaporizer 220. For example, the second supply line P_221 may provide a path along which the atomizing gas AG stored in the atomizing gas tank T_221 moves to the internal space of the frame Pr_220 of the vaporizer 220. For example, a pressure of the atomizing gas AG stored in the atomizing gas tank T_221 is higher than a pressure of the internal space of the vaporizer 220 so that the atomizing gas AG stored in the atomizing gas tank T_221 may move to the internal space of the vaporizer 220 along the second supply line P_221.

According to some embodiments, the second supply line P_221 may be connected to the inflow portion Pr_220_A of the frame Pr_220. For example, the second supply line P_221 may be connected to the frame Pr_220 such as to be adjacent to the first supply line P_210.

According to some embodiments, the atomizing gas AG discharged into the internal space of the frame Pr_220 from the second supply line P_221 may strike the precursor PR introduced into the internal space of the frame Pr_220 from the first supply line P_210. Accordingly, the precursor PR bombarded by the atomizing gas AG may be atomized into small particles.

According to some embodiments, the atomizing gas AG may be gas that is lowly reactive with the precursor PR. For example, the atomizing gas AG may comprise argon (Ar), nitrogen (N), carbon dioxide (CO), and helium (He).

According to some embodiments, an end of the second supply line P_221 may face an end of the first supply line P_210. For example, the end of the second supply line P_221 may be disposed to surround the first supply line P_210. For example, the end of the second supply line P_221 may be disposed so that the atomizing gas AG discharged from the second supply line P_221 strikes the precursor PR discharged from the first supply line P_210.

The second flow regulator R_221 may be provided on the second supply line P_221 to control the flow rate of the atomizing gas AG passing through the second supply line P_221. According to some embodiments, the second flow regulator R_221 may be switched from an open position or a closed position. When the second flow regulator R_221 is at the open position, the second supply line P_221 may be open so that the atomizing gas AG may move into the internal space of the frame Pr_220 of the vaporizer 220. When the second flow regulator R_221 is at the closed position, the second supply line P_221 may be closed so that the atomizing gas AG may not be provided into the internal space of the frame Pr_220 of the vaporizer 220. However, the inventive concept is not limited thereto, and the second flow regulator R_221 may regulate the supply amount of the atomizing gas AG provided from the atomizing gas tank T_221 to the frame Pr_220.

The second atomization device 222 may apply an external force to the precursor PR introduced into the internal space of the frame Pr_220 of the vaporizer 220. For example, the second atomization device 222 may be spaced apart from the precursor PR, and may apply an external force to the precursor PR via another material.

The second atomization device 222 may be located in the inflow portion Pr_220_A of the frame Pr_220. For example, the second atomization device 222 may apply an external force to the precursor PR discharged from the first supply line P_210 to atomize the precursor PR into small droplets. For example, the precursor PR atomized by the first atomization device 221 may be atomized once more by the second atomization device 222. Accordingly, the size of each of atomized precursor PR particles may be further reduced.

The size of each of the atomized precursors PR may be reduced through the first atomization device 221 and the second atomization device 222 so that the vaporization speed and vaporization efficiency of the precursor PR may be improved.

The second atomization device 222 may comprise a stop mode, a low energy mode, and a high energy mode. For example, the stop mode of the second atomization device 222 may be a state in which power is not supplied to the second atomization device 222. In other words, the stop mode of the second atomization device 222 may be a state in which the second atomization device 222 is turned off.

The low energy mode of the second atomization device 222 may be a state in which the magnitude of the external force applied by the second atomization device 222 to the precursor PR introduced into the internal space of the frame Pr_220 is relatively small. The high energy mode of the second atomization device 222 may be a state in which the magnitude of the external force applied by the second atomization device 222 to the precursor PR introduced into the internal space of the frame Pr_220 is relatively large. That is, the magnitude of the external force that the second atomization device 222 applies to the precursor PR when the second atomization device 222 is in the low energy mode may be less than the magnitude of the external force that the second atomization device 222 applies to the precursor PR when the second atomization device 222 is in the high energy mode.

When the intensity of the external force applied to the precursor PR by the second atomization device 222 exceeds a certain intensity, the atomized precursor PR may be radicalized. When the second atomization device 222 is in the high energy mode, the atomized precursors PR may be radicalized, and thus the substrate deposition apparatus 1000 may perform an atomic layer deposition (ALD) process on the substrate W through radicalized precursors PR.

For convenience of explanation, a case in which the substrate deposition apparatus 1000 performs a deposition process on the substrate W through a first precursor will be illustrated. When the second atomization device 222 is in the low energy mode or the stop mode, the first precursor is in a stabilized state, and thus the substrate deposition apparatus 1000 may not perform an ALD process on the substrate W. However, even when the substrate deposition apparatus 1000 uses the same first precursor, when the second atomization device 1000 is in the high energy mode, the first precursor may be radicalized, and thus the substrate deposition apparatus 1000 may perform an ALD process on the substrate W.

According to some embodiments, the second atomization device 222 may comprise an ultrasonic generator that generates ultrasonic waves to apply an external force to the precursor PR. As the frequency of ultrasonic waves generated by the ultrasonic generator of the second atomization device 222 increases, the magnitude of the external force applied by the second atomization device 222 to the precursor PR may increase. For example, as the frequency of the ultrasonic waves increases, the vibration of the precursor PR increases, so the precursor PR may be atomized into smaller particles.

For example, when the frequency of the ultrasonic waves generated by the second atomization device 222 exceeds a certain value, the precursor PR may be radicalized. A radicalized precursor PR has increased reactivity, and accordingly may be used in an ALD process.

For example, the frequency of the ultrasonic waves generated by the ultrasonic generator of the second atomization device 222 when the second atomization device 222 is in the high energy mode may be greater than the frequency of the ultrasonic waves generated by the ultrasonic generator of the second atomization device 222 when the second atomization device 222 is in the low energy mode.

According to some embodiments, when the second atomization device 222 is in the low energy mode, the frequency of the ultrasonic waves generated by the ultrasonic generator of the second atomization device 222 may be 40 kHz to 120 kHz. The frequency of the ultrasonic waves generated by the ultrasonic generator of the second atomization device 222 when the second atomization device 222 is in the high energy mode may be 10 to 1000 times the frequency of the ultrasonic waves generated by the ultrasonic generator of the second atomization device 222 when the second atomization device 222 is in the low energy mode.

For example, the frequency of the ultrasonic waves generated by the ultrasonic generator of the second atomization device 222 when the second atomization device 222 is in the low energy mode may be a first frequency. The frequency of the ultrasonic waves generated by the ultrasonic generator of the second atomization device 222 when the second atomization device 222 is in the high energy mode may be a second frequency that is greater than the first frequency. For example, the first frequency may be 40 kHz to 120 kHz, and the second frequency may be 10 to 1000 times the first frequency (e.g. one to three orders of magnitude greater than the first frequency, so 400 kHz to 120 MHz in some embodiments).

The heating device 223 may be provided on the frame Pr_220 and may heat the internal space of the frame Pr_220. According to some embodiments, the heating device 223 may be provided near a sidewall of the frame Pr_220. For example, the heating device 223 may heat the precursor PR introduced into the internal space of the frame Pr_220.

For example, the precursor PR in a liquid state introduced into the internal space of the frame Pr_220 may be atomized into small droplets by the first atomization device 221 and the second atomization device 222, and the atomized precursors PR may be heated by the heating device 223 and thus may be vaporized.

The precursor supply unit 200 may further comprise a third supply line P_220. The third supply line P_220 may connect the vaporizer 220 to the process chamber 100. For example, the third supply line P_220 may provide a path along which a precursor PR′ vaporized by the vaporizer 220 moves from the frame Pr_220 to the process chamber 100.

The third supply line P_220 may be connected to the frame Pr_220 of the vaporizer 220. For example, the third supply line P_220 may be disposed opposite to the inflow portion Pr_220_A of the frame Pr_220. For example, the inflow portion Pr_220_A of the frame Pr_220 may refer to the ceiling portion of the frame Pr_220, and the third supply line P_220 may be connected to the bottom of the frame Pr_220.

Referring back to FIG. 1, the reactant supply unit 300 may supply a reactant RE to the process chamber 100. For example, the reactant supply unit 300 may supply the reactant RE to the processing space of the process chamber 100.

The reactant supply unit 300 may further comprise a reactant tank T_300, a fourth supply line P_300, and a third flow regulator R_300. The reactant tank T_210 may provide a space for storing the reactant RE that is to be provided to the process chamber 100. For example, the reactant RE may be stored in an internal space of the reactant tank T_300.

For example, the reactant RE may comprise water (H₂O), ammonia (NH₃), ozone (O₃), and hydrogen (H₂). For example, the reactant RE may react with the precursor PR to form a thin film on the deposition surface of the substrate W. According to some embodiments, the reactant RE stored in the reactant tank T_300 may be in a gaseous state.

The fourth supply line P_300 may connect the reactant tank T_300 to the process chamber 100. For example, the fourth supply line P_300 may provide a path along which the reactant RE moves from the reactant tank T_300 to the process chamber 100. The reactant RE stored in the reactant tank T_300 may move to the processing space of the process chamber 100 through the fourth supply line P_300.

The third flow regulator R_300 may be provided on the fourth supply line P_300. For example, the third flow regulator R_300 may regulate a flow rate of the reactant RE passing through the fourth supply line P_300. For example, the supply amount of the reactant RE flowing from the reactant tank T_300 to the process chamber 100 may be controlled through the third flow regulator R_300.

For example, the third flow regulator R_300 may comprise a ball valve, a globe valve, a gate valve, a diaphragm valve, and an electronic pressure regulator.

The purge supply unit 400 may supply purge gas PU to the process chamber 100. For example, the purge supply unit 400 may supply the purge gas PU in a gaseous state to the processing space of the process chamber 100.

The purge supply unit 400 may further comprise a purge gas tank T_400, a fifth supply line P_400, and a fourth flow regulator R_400. The purge gas tank T_400 may provide a space for storing the purge gas PU that is to be provided to the process chamber 100. For example, the purge gas PU may be stored in an internal space of the purge gas tank T_400.

For example, the purge gas PU may comprise argon (Ar), nitrogen (N), carbon dioxide (CO), and helium (He).

The fifth supply line P_400 may connect the purge gas tank T_400 to the process chamber 100. For example, the fifth supply line P_400 may provide a path along which the purge gas PU moves from the purge gas tank T_400 to the process chamber 100. The purge gas PU stored in the purge gas tank T_400 may move to the processing space of the process chamber 100 through the fifth supply line P_400.

The fourth flow regulator R_400 may be provided on the fifth supply line P_400 to control the flow rate of the purge gas PU passing through the fifth supply line P_400. According to some embodiments, the fourth flow regulator R_400 may be switched from an open position or a closed position. When the fourth flow regulator R_400 is at the open position, the fifth supply line P_400 may be open so that the purge gas PU may move into the processing space of the process chamber 100. When the fourth flow regulator R_400 is at the closed position, the fifth supply line P_400 may be closed so that the purge gas PU may not be supplied to the processing space of the process chamber 100.

The controller 500 may control the precursor supply unit 200, the reactant supply unit 300, and the purge supply unit 400. For example, the controller 500 may be connected to the precursor supply unit 200, the reactant supply unit 300, and the purge supply unit 400 by wire or wirelessly.

The controller 500 may control the supply amount of the precursor PR that the precursor supply unit 200 supplies. The controller 500 may control the supply amount of the reactant RE that the reactant supply unit 300 supplies. The controller 500 may control the supply amount of the purge gas PU that the purge supply unit 400 supplies. The controller 500 may be a computer (or several interconnected computers) and may include, for example, one or more processors configured by software, such as a CPU (Central Processing Unit), GPU (graphics processor), controller, etc. The computer may be a general purpose computer or may be dedicated hardware or firmware (e.g., an electronic or optical circuit, such as application-specific hardware, such as, for example, a digital signal processor (DSP) or a field-programmable gate array (FPGA)). The controller 500 may include storage such as conventional memory of a computer, such as a hard drive (which may be a solid state drive, DRAM, NAND flash memory, etc.), and may include memory such as DRAM or other volatile memory. Controller 500 may comprise a conventional computer user interface and include convention input devices, such as a keyboard, mouse, trackpad, touchscreen, etc., and may be connected to various components of the precursor supply unit 200, the reactant supply unit 300, and the purge supply unit 400 to control their operation based on computer program code and/or user selections.

According to some embodiments, the controller 500 may control a target flow rate of the first flow regulator R_210 of the precursor supply unit 200. The controller 500 may control a target flow rate of the third flow regulator R_300 of the reactant supply unit 300. For example, the target flow rate of the first flow regulator R_210 may refer to the flow rate of the precursor PR passing through the first supply line P_210. The target flow rate of the third flow regulator R_300 may refer to the flow rate of the reactant RE passing through the fourth supply line P_300.

The controller 500 may switch the first flow regulator R_210 between the small-volume supply mode and the large-volume supply mode. For example, the controller 500 may control the target flow rate of the first flow regulator R_210 to control the flow rate of the precursor supplied from the canister 210 to the vaporizer 220.

According to some embodiments, the controller 500 may switch the fourth flow regulator R_400 between the open position and the closed position. For example, the controller 500 may control supply or non-supply of the purge gas PU by the purge supply unit 400. However, the inventive concept is not limited thereto, and the controller 500 may control a target flow rate of the fourth flow regulator R_400. The target flow rate of the fourth flow regulator R_400 refers to the flow rate of purge gas PU passing through the fifth supply line P_400.

For example, the controller 500 may reduce or increase the supply amount of the precursor PR, the supply amount of the reactant RE, and the supply amount of the purge gas PU according to the cycle of the deposition process of the substrate deposition apparatus 1000.

According to some embodiments, the controller 500 may control the first atomization device 221 and the second atomization device 222 of the vaporizer 220 of the precursor supply unit 200.

For example, the controller 500 may operate or stop the first atomization device 221. The controller 500 may control the second flow regulator R_221 of the first atomization device 221 to open or close the second supply line P_221. When the controller 500 switches the second flow regulator R_221 of the first atomization device 221 to the open position to open the second supply line P_221, the first atomization device 221 may operate. On the other hand, when the controller 500 switches the second flow regulator R_221 of the first atomization device 221 to the closed position to close the second supply line P_221, the first atomization device 221 may stop.

For example, the controller 500 may switch the second atomization device 222 between the stop mode, the low energy mode, and the high energy mode. According to some embodiments, the controller 500 may control the ultrasonic generator of the second atomization device 222. The second atomization device 222 enters a stop mode when the controller 500 cuts off power supply to the ultrasonic generator of the second atomization device 222, and the controller 500 may switch the second atomization device 222 to a high energy mode or a low energy mode by adjusting the frequency of the ultrasonic waves generated by the ultrasonic generator of the second atomization device 222.

According to some embodiments, when the controller 500 switches the second atomization device 222 to a high energy mode, the controller 500 may switch the first flow regulator R_210 to a small-volume supply mode. When the controller 500 switches the second atomization device 222 to a low energy mode, the controller 500 may switch the first flow regulator R_210 to a large-volume supply mode. For example, the controller 500 may simultaneously control a mode of the second atomization device 222 and a mode of the first flow regulator R_210. For example, the controller 500 may switch the mode of the first flow regulator R_210 in accordance with the mode of the second atomization device 222.

According to some embodiments, while the substrate deposition apparatus 1000 is performing a deposition process on the substrate W, which is a deposition target, the controller 500 may change the mode of the second atomization device 222. For example, while the substrate deposition apparatus 1000 is performing one deposition process, the controller 500 may switch the second atomization device 222 between a high energy mode and a low energy mode. Accordingly, one deposition process performed on one substrate by the substrate deposition apparatus 1000 may comprise a cycle in which the second atomization device 222 operates in a high energy mode and a cycle in which the second atomization device 222 operates in a low energy mode.

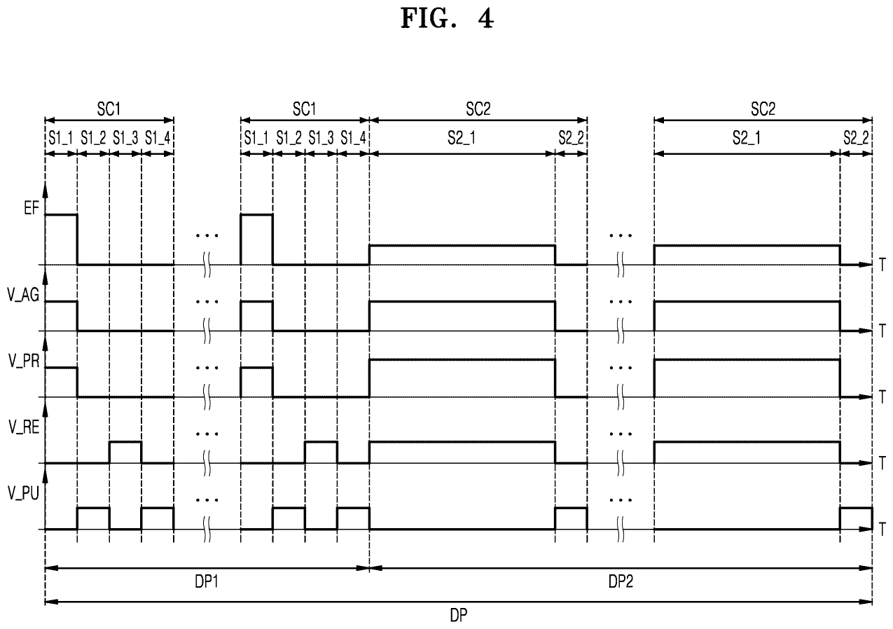

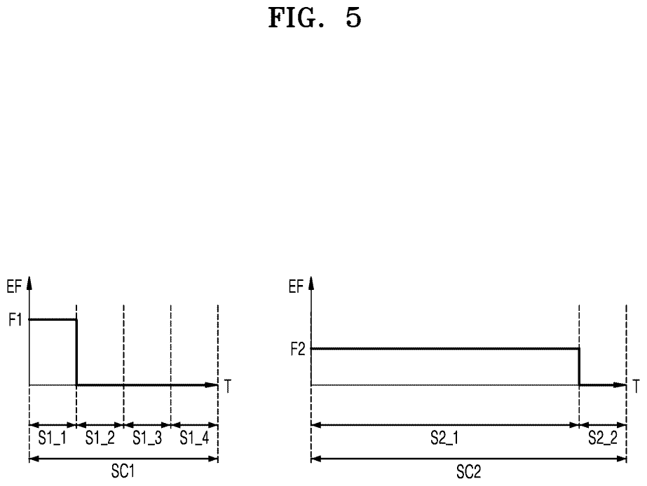

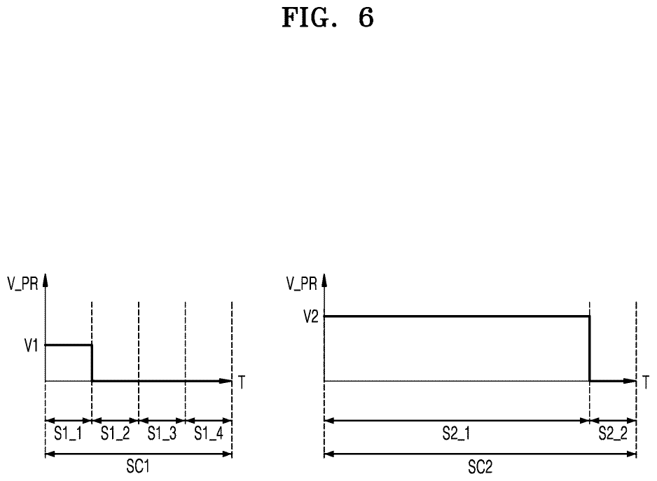

FIG. 4 depicts graphs showing respective supply amounts of materials and an external force during a deposition process DP of the substrate deposition apparatus 1000 according to an embodiment. FIG. 5 is a graph showing an external force provided through the second atomization device 222 during the deposition process DP of the substrate deposition apparatus 1000 according to an embodiment. FIG. 6 is a graph showing a supply amount V_PR of the precursor PR provided through the canister 210 during the deposition process DP of the substrate deposition apparatus 1000 according to an embodiment.

In detail, FIG. 4 depicts graphs respectively showing a change in an external force EF applied to the precursor PR by the second atomization device 222, a change in a supply amount V_AG of the atomizing gas AG, a change in a supply amount V_PR of the precursor PR, a change in a supply amount V_RE of the reactant RE, and a change in a supply amount V_PU of the purge gas PU, while the substrate deposition apparatus 1000 is performing the deposition process DP on the substrate W, which is a deposition target.

The graphs of FIG. 4 show, in order from the top, a change in the external force EF, a change in the supply amount V_AG of the atomizing gas AG, a change in the supply amount V_PR of the precursor PR, a change in the supply amount V_RE of the reactant RE, and a change in the supply amount V_PU of the purge gas PU.

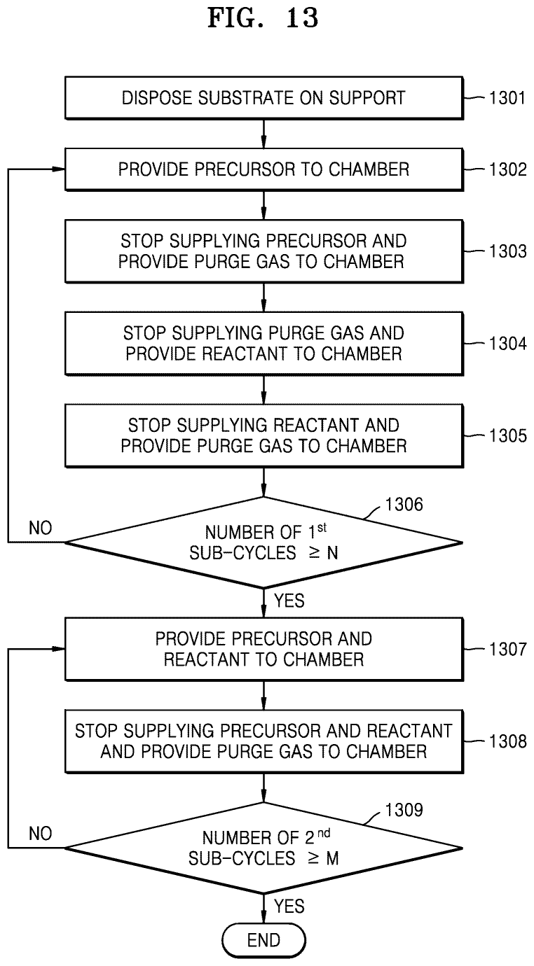

FIG. 5 is a portion of the graph showing the external force EF applied to the precursor PR by the second atomization device 222 from among the graphs of FIG. 4, and FIG. 6 is a portion of the graph showing a change in the supply amount V_PR of the precursor PR from among the graphs of FIG. 4. FIG. 13 is a flowchart showing the process depicted in FIGS. 4 through 6 as part of a method of manufacturing a semiconductor device.

Referring to FIGS. 4 through 6 and 13 together with FIGS. 1 through 3, the deposition process DP of the substrate deposition apparatus 1000 will be described. In this specification, the deposition process DP of the substrate deposition apparatus 1000 refers to a deposition process DP performed on one substrate W by the substrate deposition apparatus 1000. For example, the deposition process DP of the substrate deposition apparatus 1000 may refer to one deposition process performed to form a thin film with a target thickness on one substrate W.

The deposition process DP of the substrate deposition apparatus 1000 may comprise a first deposition process DP1 and a second deposition process DP2 performed after the first deposition process DP1. For example, the first deposition process DP1 may be a step in which a first sub-cycle SC1 is repeatedly performed a plurality of number of times, and the second deposition process DP2 may be a step in which a second sub-cycle SC2 is performed at least once. In other words, in the deposition process DP of the substrate deposition apparatus 1000, the first sub-cycle SC1 may be repeatedly performed a plurality of number of times, and the second sub-cycle SC2 may be performed at least once.

Initially (step 1301) a substrate W is disposed on a support C in a process chamber 100. For example, the substrate W may have undergone other process steps in one of more other chambers as part of a method of manufacturing a semiconductor device, and may be newly placed on the support C, or the substrate W may have undergone one or more processes already in the chamber 100 and so may already be in the chamber 100. Next (steps 1302-1305), the first sub-cycle SC1 is performed. The first sub-cycle SC1 of the first deposition process DP1 may comprise four steps. A first step S1_1 of the first sub-cycle SC1 may be a step of providing the precursor PR to the process chamber 100 (step 1302). A second step S1_2 of the first sub-cycle SC1 may be a step of stopping supply of the precursor PR and providing the purge gas PU to the process chamber 100 (step 1303). A third step S1_3 of the first sub-cycle SC1 may be a step of stopping supply of the purge gas PU and providing the reactant RE to the process chamber 100 (step 1304). A fourth step S1_4 of the first sub-cycle SC1 may be a step of stopping supply of the reactant RE and providing the purge gas PU to the process chamber 100 (step 1305). Then, it is determined whether the total number of sub-cycles of the first sub-cycle SC1 has reached a threshold amount of N sub-cycles, where N is an integer of 2 or more (step 1306). If not (NO), the process continues back at step 1302. If so (YES), the process continues to the second sub-cycle SC2.

The second sub-cycle SC2 of the second deposition process DP2 may comprise two steps. A first step S2_1 of the second sub-cycle SC2 may be a step of providing the precursor PR and the reactant RE to the process chamber 100 (step 1307). A second step S2_2 of the second sub-cycle SC2 may be a step of stopping supply of the precursor PR and the reactant RE and providing the purge gas PU to the process chamber 100 (step 1308). Then, it is determined whether the total number of sub-cycles of the second sub-cycle SC2 has reached a threshold amount of M sub-cycles, where M is an integer of 1 or more (step 1309). If not (NO), the process continues back at step 1307. If so (YES), the process ends (END). Subsequently to the deposition process depicted in FIG. 13, additional manufacturing steps may be performed, such as etching, more deposition steps, bonding, etc., to form a plurality of semiconductor devices such as semiconductor chips (e.g., processor chips or memory chips) on the substrate, and then the chips maybe separated from each other (e.g., singulated) through a dicing process.

According to the above description, a method for depositing a material layer on a substrate W may include vaporizing a precursor PR by spraying atomizing gas AG to the precursor PR while a first external force is applied to the precursor, for example using an atomization device 222 of a vaporizer 220, during a first deposition sub-cycle (S1_1) to result in a first vaporized precursor, and introducing the first vaporized precursor to a chamber 100 in which the substrate W is disposed during the first deposition sub-cycle. The method may further include vaporizing the precursor PR by spraying the atomizing gas AG to the precursor PR while a second external force is applied to the precursor during a second deposition sub-cycle that follows the first deposition sub-cycle to result in a second vaporized precursor, and introducing the second vaporized precursor to the chamber 100 in which the substrate W remains disposed during the second deposition sub-cycle. Vaporizing the precursor PR during the first sub-cycle may include spraying the atomizing gas AG toward the precursor, for example using a first atomization device 221, while applying the first external force to the precursor by a second atomization device 222, and vaporizing the precursor PR during the second sub-cycle may include spraying the atomizing gas AG toward the precursor PR while applying the second external force to the precursor PR. The first external force may be greater than the second external force, and may be implemented using an ultrasonic generator that applies an ultrasonic wave that is 10 to 1000 times the frequency during applying the first external force compared to when applying the second external force. The first sub-cycle may be repeated at least two times prior to performing the second sub-cycle, which may be performed once or may be repeated.

According to some embodiments, the first deposition process DP1 may be an ALD process, and the second deposition process DP2 may be a chemical vapor deposition (CVD). For example, the first sub-cycle SC1 of the first deposition process DP1 may provide the precursor PR and the reactant RE to the process chamber 100 in separate steps, as in ALD. The second sub-cycle SC2 of the second deposition process DP2 may simultaneously provide the precursor PR and the reactant RE to the process chamber 100, as in chemical vapor deposition (CVD). The first sub-cycles may be part of the ALD process, and the second sub-cycle or sub-cycles may be part of the CVD process. For example, in one embodiment, during the ALD process, a first layer is deposited during each first sub-cycle and during the CVD process, a second layer is deposited during each second sub-cycle, wherein a thickness of the layer deposited during each first sub-cycle is less than a thickness of the layer deposited during each second sub-cycle, and the same material is deposited during each first sub-cycle as during each second sub-cycle. Thus, a single material layer may be deposited using a combination of an ALD process and a CVD process. Therefore, as part of a deposition process to form a layer on a substrate in a chamber, both an ALD process and a CVD process may be performed in situ (e.g., in the same chamber without a vacuum break), and the same material may be formed (e.g., deposited) on the substrate using a combination of the ALD process and the CVD process. The ALD process may be performed by alternately first supplying a precursor with a source gas to the chamber while not supplying a reactant to the chamber and second supplying the reactant to the chamber while not supplying the precursor or source gas (with steps of supplying purge gas in between). Subsequent to performing the ALD and without removing the substrate from the chamber, the CVD process may be performed by third supplying the precursor with the source gas to the chamber while simultaneously supplying the reactant to the chamber. The combined ALD process and CVD process results in depositing the material layer on the substrate

A proceeding time of the first deposition process DP1 may be shorter than a proceeding time of the second deposition process DP2. For example, a time required or used for the first sub-cycle SC1 to be repeated multiple times may be shorter than a time required or used for the second sub-cycle SC2 to be repeated multiple times or even just once.

A time required or used for each first sub-cycle SC1 to be performed may be shorter than a time required or used for each second sub-cycle SC2 to be performed. In particular, a time required or used for the first step S1_1 of the first sub-cycle SC1 may be shorter than a time required or used for first step S2_1 of the second sub-cycle SC2.

According to some embodiments, the first sub-cycle SC1 is a step of forming a thin film as one layer at a time, and a thin film deposition speed in the first sub-cycle SC1 may be slower than a thin film deposition speed in the second sub-cycle SC2.

The first deposition process DP1 and the second deposition process DP2 of the substrate deposition apparatus 1000 may be performed as the controller 500 controls the precursor supply unit 200, the reactant supply unit 300, and the purge supply unit 400. Therefore, under control by the controller 500, the deposition process DP of the substrate deposition apparatus 1000 may be performed.

The first atomization device 221 and the second atomization device 222 are devices for atomizing the precursor PR introduced into the internal space of the frame Pr_220 of the vaporizer 220 into small particles, and the controller 500 may operate the first atomization device 221 and the second atomization device 222 in a step where the precursor PR is supplied to the process chamber 100.

While the substrate deposition apparatus 1000 is performing the first sub-cycle SC1, the controller 500 may switch the second atomization device 222 between a high energy mode and a stop mode. For example, the controller 500 may switch the second atomization device 222 to a high energy mode in the first step S1_1 of the first sub-cycle SC1, and may switch the second atomization device 222 to a stop mode in the second step S1_2 through to the fourth step S1_4 of the first sub-cycle SC1.

While the substrate deposition apparatus 1000 is performing the second sub-cycle SC2, the controller 500 may switch the second atomization device 222 between a low energy mode and a stop mode. For example, the controller 500 may switch the second atomization device 222 to a low energy mode in the first step S2_1 of the second sub-cycle SC2, and may switch the second atomization device 222 to a stop mode in the second step S2_2 of the second sub-cycle SC2.

Referring to FIG. 5, in the first step S1_1 of the first sub-cycle SC1, the magnitude of the external force EF applied by the second atomization device 222 to the precursor PR may be a first force F1, and, in the first step S2_1 of the second sub-cycle SC2, the magnitude of the external force EF applied by the second atomization device 222 to the precursor PR may be a second force F2. The second force F2 may be less than the first force F1.

According to some embodiments, the frequency of the ultrasonic waves generated by the ultrasonic generator of the second atomization device 222 in the first step S1_1 of the first sub-cycle SC1 may be greater than the frequency of the ultrasonic waves generated by the ultrasonic generator of the first atomization device 221 in the first step S2_1 of the second sub-cycle SC2.

The particle size of the precursor PR atomized in the vaporizer 220 in the first step S1_1 of the first sub-cycle SC1 may be less than the particle size of the precursor PR atomized in the vaporizer 220 in the first step S2_1 of the second sub-cycle SC2.

According to some embodiments, a time required or used for the first step S1_1 of the first sub-cycle SC1 may be less than a time required or used for the first step S2_1 of the second sub-cycle SC2. Accordingly, a time taken for the controller 500 to maintain the second atomization device 222 in the high energy mode may be shorter than a time taken for the controller 500 to maintain the second atomization device 222 in the low energy mode.

In the first step S1_1 of the first sub-cycle SC1, the controller 500 may switch the first flow regulator R_210 to a small-volume supply mode. In the first step S1_1 of the first sub-cycle SC1, the controller 500 may switch the first flow regulator R_210 to a small-volume supply mode, and may switch the second atomization device 222 to the high energy mode.

In the first step S2_1 of the second sub-cycle SC2, the controller 500 may switch the first flow regulator R_210 to a large-volume supply mode. In the first step S2_1 of the second sub-cycle SC2, the controller 500 may switch the first flow regulator R_210 to a large-volume supply mode, and may switch the second atomization device 222 to the low energy mode.

Referring to FIG. 6, in the first step S1_1 of the first sub-cycle SC1, the precursor PR may be supplied from the canister 210 to the vaporizer 220 at a first flow rate V1, and, in the first step S2_1 of the second sub-cycle SC2, the precursor PR may be supplied from the canister 210 to the vaporizer 220 at a second flow rate V2. The first flow rate V1 may be less than the second flow rate V2.

Referring back to FIG. 4, when the precursor supply unit 200 supplies the precursor PR to the process chamber 100, for example, when the canister 210 supplies the precursor PR to the vaporizer 220, the controller 500 may control the second flow regulator R_221 of the first atomization device 221 so that the atomizing gas AG is sprayed onto the precursor PR supplied to the vaporizer 220.

According to some embodiments, the amount of atomizing gas AG sprayed onto the precursor PR introduced into the vaporizer 220 in the first step S1_1 of the first sub-cycle SC1 may be substantially the same as the amount of atomizing gas AG sprayed onto the precursor PR introduced into the vaporizer 220 in the first step S2_1 of the second sub-cycle SC2, but the duration and force may vary in an inversely proportional manner.

In the first step S1_1 of the first sub-cycle SC1, the controller 500 may control the reactant supply unit 300 so that a supply amount V_RE of the reactant RE is 0, and control the purge supply unit 400 so that a supply amount V_PU of the purge gas PU is 0.

When the controller 500 switches the first flow regulator R_210 to a small-volume supply mode and switches the second atomization device 222 to a high energy mode, the controller 500 may control the third flow regulator R_300 of the reactant supply unit 300 so that the reactant RE is not supplied to the process chamber 100, and may control the fourth flow regulator R_400 of the purge supply unit 400 so that the purge gas PU is not supplied to the process chamber 100.

In the first step S2_1 of the second sub-cycle SC2, the controller 500 may control the reactant supply unit 300 so that the supply amount V_RE of the reactant RE is a positive number, and control the purge supply unit 400 so that the supply amount V_PU of the purge gas PU is 0.

When the controller 500 switches the first flow regulator R_210 to a large-volume supply mode and switches the second atomization device 222 to a low energy mode, the controller 500 may control the third flow regulator R_300 of the reactant supply unit 300 so that the reactant RE is supplied to the process chamber 100, and may control the fourth flow regulator R_400 of the purge supply unit 400 so that the purge gas PU is not supplied to the process chamber 100.

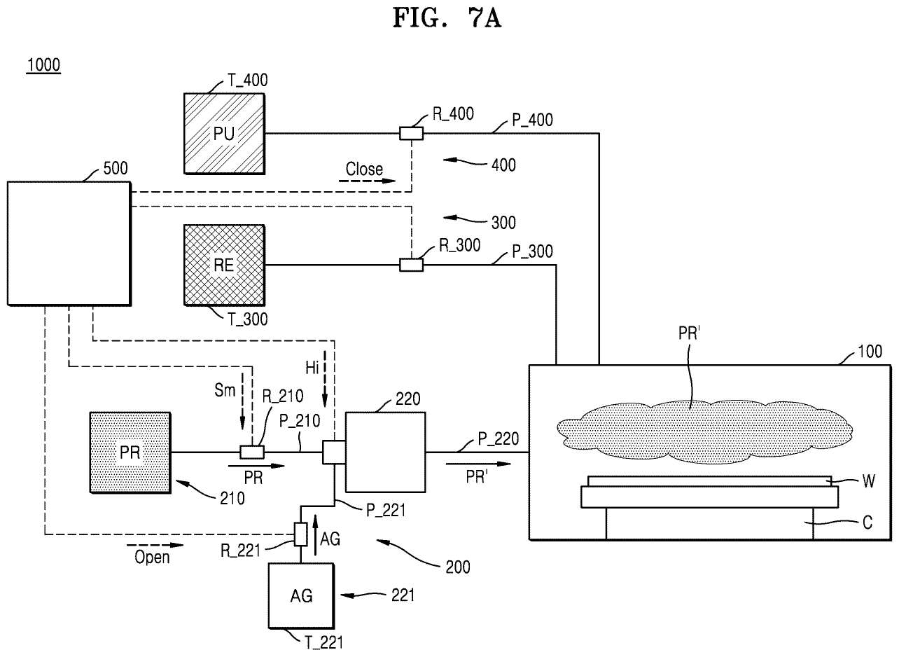

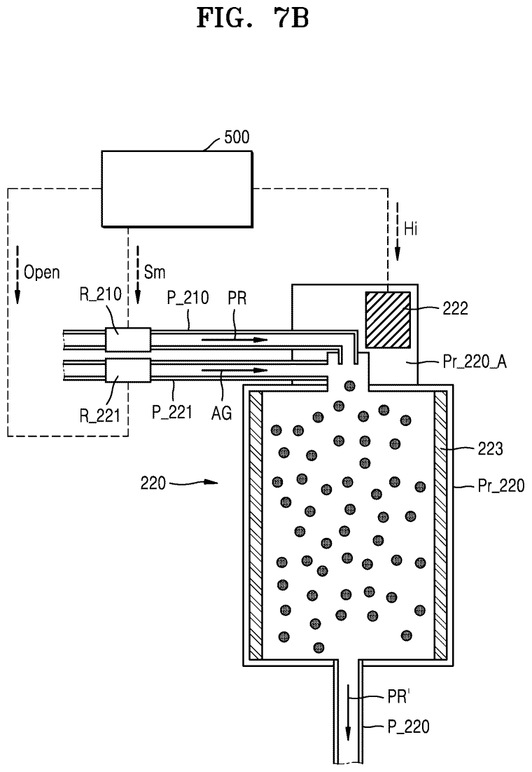

FIGS. 7A, 7B, 8 through 10, 11A, 11B, and 12 are diagrams sequentially illustrating steps in which the substrate deposition apparatus 1000 performs the deposition process DP, according to an embodiment.

Referring to FIGS. 7A, 7B, 8 through 10, 11A, 11B, and 12 together with FIG. 4, steps in which the controller 500 controls the precursor supply unit 200, the reactant supply unit 300, and the purge supply unit 400 while the substrate deposition apparatus 1000 is performing the deposition process DP will now be described.

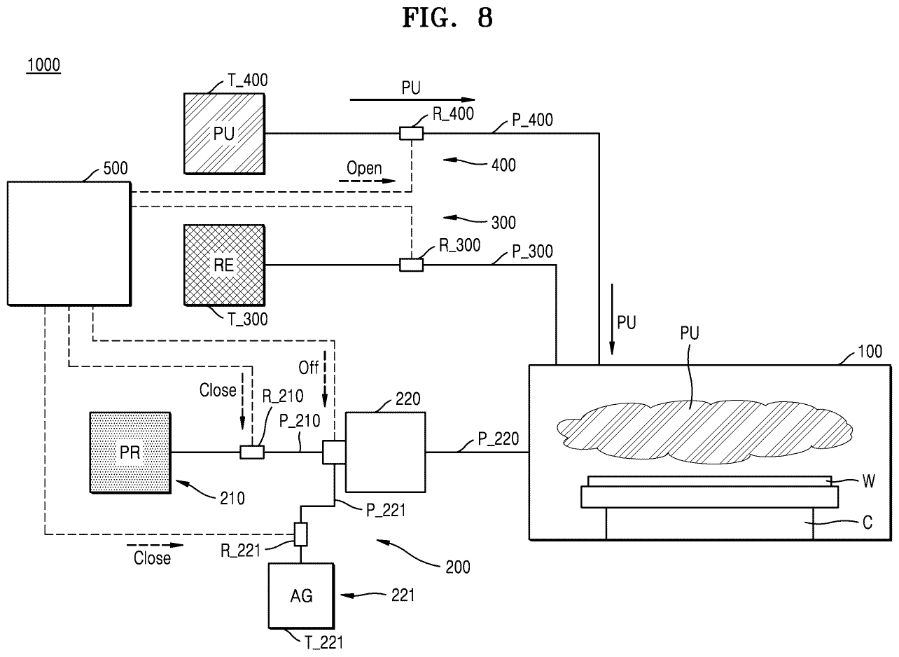

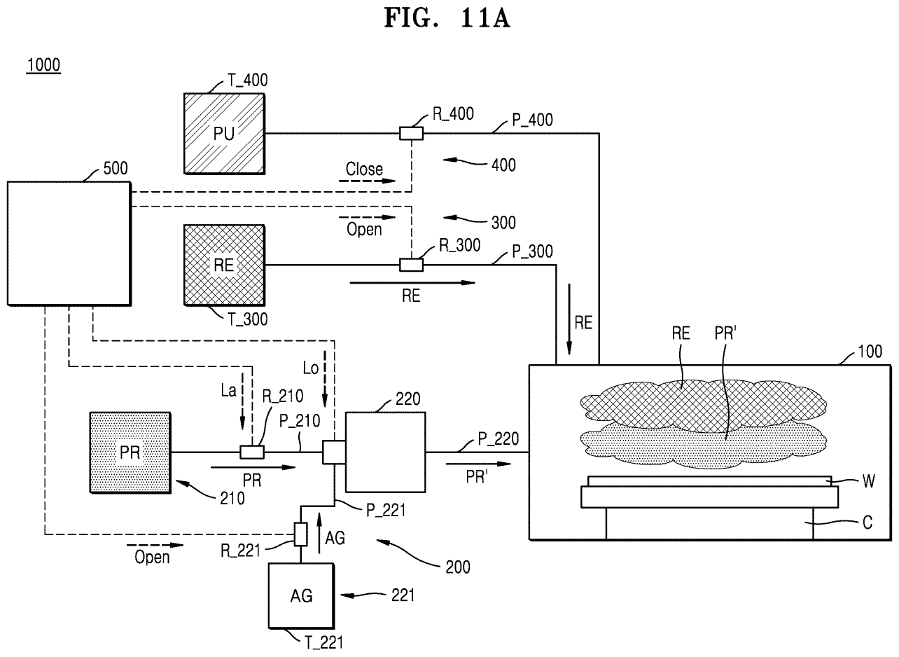

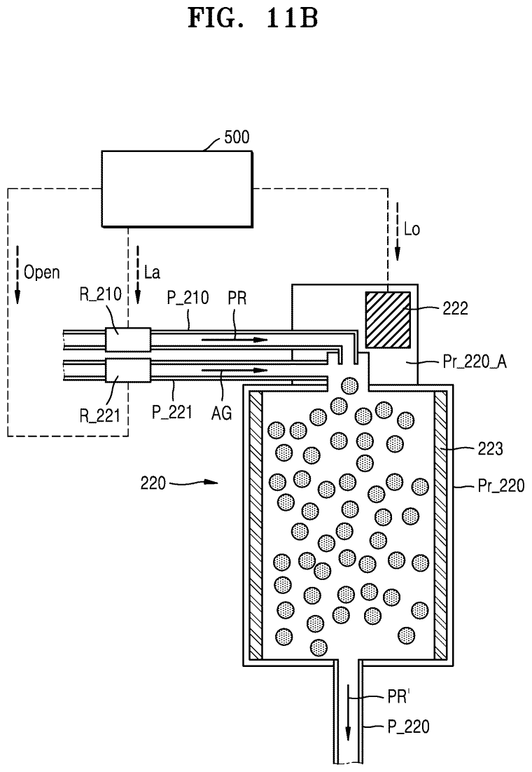

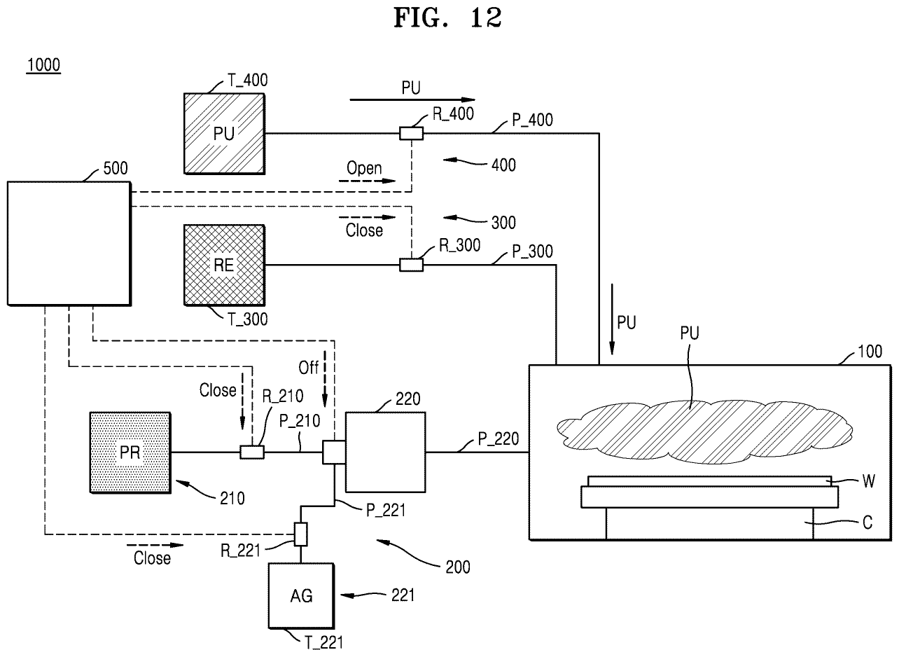

FIG. 7A, FIG. 7B, and FIGS. 8 through 10 sequentially illustrate that the substrate deposition apparatus 1000 performs the first sub-cycle SC1 once in the first deposition process DP1, and FIG. 11A, FIG. 11B, and FIG. 12 sequentially illustrate that the substrate deposition apparatus 1000 performs the second sub-cycle SC2 once in the second deposition process DP2.

For example, the first deposition process DP1 may be a process of repeating FIG. 7A, FIG. 7B, and FIGS. 8 through 10 multiple times, and the second deposition process DP2 may be a process of performing FIGS. 11A, 11B, and 12 at least once.

FIGS. 7A and 7B illustrate the first step S1_1 of the first sub-cycle SC1. Referring to FIGS. 7A and 7B, the controller 500 may control the first flow regulator R_210 of the precursor supply unit 200, the second flow regulator R_221 of the precursor supply unit 200, and the second atomization device 222 of the vaporizer 220. For example, the controller 500 may switch the first flow regulator R_210 to a small-volume supply mode, switch the second flow regulator R_221 to an open position, and switch the second atomization device 222 to a high energy mode.

According to some embodiments, the controller 500 may switch the fourth flow regulator R_400 of the purge supply unit 400 to the closed position so that the purge gas PU is not supplied to the process chamber 100.

The canister 210 may transmit the precursor PR to the internal space of the frame Pr_220 of the vaporizer 220 at the first flow rate V1 (see FIG. 6). The precursor PR introduced into the internal space of the frame Pr_220 of the vaporizer 220 may be bombarded and atomized by the atomizing gas AG. The precursor PR introduced into the internal space of the frame Pr_220 of the vaporizer 220 may be atomized one more time by the second atomization device 222.

In the first step S1_1 of the first sub-cycle SC1, the precursor PR atomized by the second atomization device 222 in a high energy mode may be radicalized. For example, the precursor PR exposed to high-frequency ultrasonic waves generated by the ultrasonic generator of the second atomization device 222 may be radicalized, and used in an ALD process.

The radicalized and atomized precursor PR may be heated by the heating device 223 of the vaporizer 220, and thus vaporized. The vaporized precursor PR′ may be supplied to the process chamber 100 through the third supply line P_220.

FIG. 8 illustrates the second step S1_2 of the first sub-cycle SC1. Referring to FIG. 8, the controller 500 may control the precursor supply unit 200 and the purge supply unit 400.

The controller 500 may switch the first flow regulator R_210 and the second flow regulator R_221 to a closed mode, and may switch the second atomization device 222 to a stop mode. At the same time, the controller 500 may switch the fourth flow regulator R_400 to an open position. Accordingly, the precursor supply unit 200 may not supply the precursor PR to the process chamber 100, and the purge supply unit 400 may supply the purge gas PU to the process chamber 100.

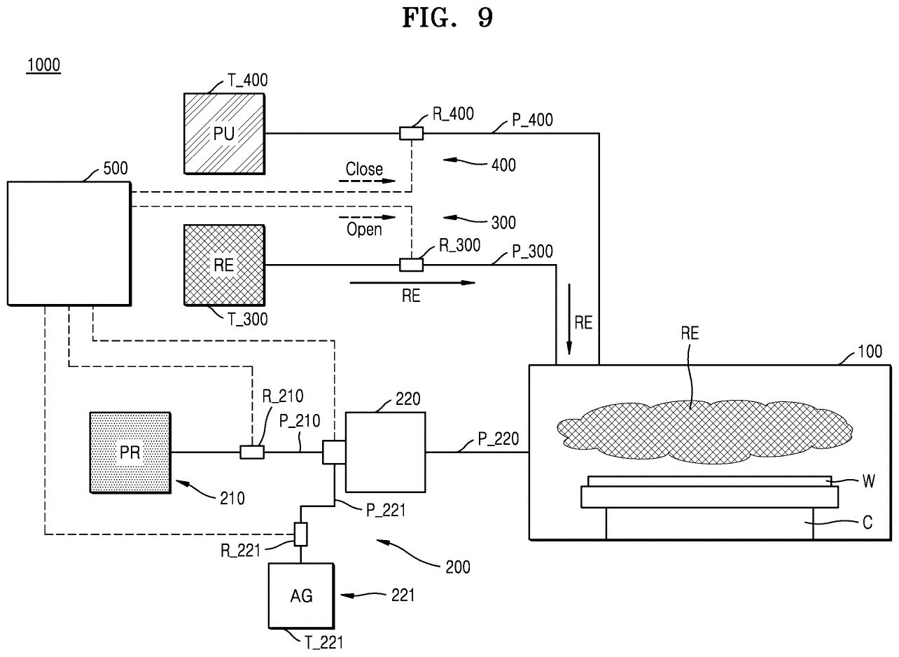

FIG. 9 illustrates the third step S1_3 of the first sub-cycle SC1. Referring to FIG. 9, the controller 500 may control the purge supply unit 400 and the reactant supply unit 300.

The controller 500 may switch the fourth flow regulator R_400 to a closed mode, and may switch the third flow regulator R_300 to an open mode. Accordingly, the purge supply unit 400 may not supply the purge gas PU to the process chamber 100, and the reactant supply unit 300 may supply the reactant RE to the process chamber 100.

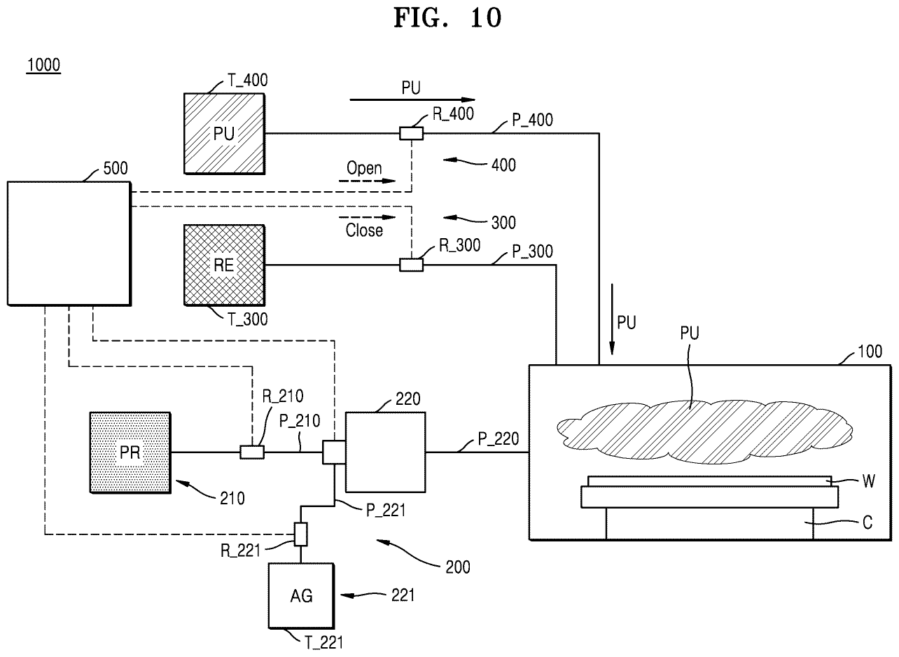

FIG. 10 illustrates the fourth step S1_4 of the first sub-cycle SC1. Referring to FIG. 10, the controller 500 may control the reactant supply unit 300 and the purge supply unit 400.

The controller 500 may switch the third flow regulator R_300 to a closed mode, and may switch the fourth flow regulator R_400 to an open mode. Accordingly, the reactant supply unit 300 may not supply the reactant RE to the process chamber 100, and the purge supply unit 400 may supply the purge gas PU to the process chamber 100.

FIGS. 11A and 11B illustrate the first step S2_1 of the second sub-cycle SC2. Referring to FIGS. 11A and 11B, the controller 500 may control the precursor supply unit 200, the reactant supply unit 300, and the purge supply unit 400.

The controller 500 may switch the first flow regulator R_210 to a large-volume supply mode, switch the second flow regulator R_221 to an open position, and switch the second atomization device 222 to a low energy mode.

The canister 210 may transmit the precursor PR to the internal space of the frame Pr_220 of the vaporizer 220 at the second flow rate V2 (see FIG. 6). The precursor PR introduced into the internal space of the frame Pr_220 of the vaporizer 220 may be bombarded and atomized by the atomizing gas AG. The precursor PR introduced into the internal space of the frame Pr_220 of the vaporizer 220 may be atomized one more time by the second atomization device 222.

The atomized precursor PR may be heated by the heating device 223 of the vaporizer 220, and thus vaporized. Vaporized precursor PR′ may be supplied to the process chamber 100 through the third supply line P_220. Because the precursor PR is atomized, the heating efficiency of the heating device 223 of the vaporizer 220 may be improved so that the vaporization speed and vaporization efficiency of the precursor PR may be improved.

The controller 500 may control the third flow regulator R_300 so that the reactant supply unit 300 supplies the reactant RE to the process chamber 100. The controller 500 may switch the third flow regulator R_300 to an open position. The controller 500 may switch the fourth flow regulator R_400 to a closed position so that the purge supply unit 400 does not supply the purge gas PU to the process chamber 100.

The vaporized precursor PR′ and the reactant RE may exist together in the processing space of the process chamber 100. Accordingly, a chemical vapor deposition process may be performed on the deposition surface of the substrate W placed in the process chamber 100.

FIG. 12 illustrates the second step S2_2 of the second sub-cycle SC2. Referring to FIG. 12, the controller 500 may control the precursor supply unit 200, the reactant supply unit 300, and the purge supply unit 400.

The controller 500 may switch the first flow regulator R_210 to a closed position so that the precursor supply unit 200 does not supply the precursor PR to the process chamber 100. Because no precursor is introduced into the vapor 220, the controller 500 may switch the second flow regulator R_221 to a closed mode to stop the first atomization device 221 and switch the second atomization device 222 to a stop mode.

The controller 500 may switch the third flow regulator R_300 to a closed position so that the reactant supply unit 300 does not supply the reactant RE to the process chamber 100. The controller 500 may switch the fourth flow regulator R_400 to an open position so that the purge supply unit 400 may supply the purge gas PU to the process chamber 100.

As described above, a method for depositing a material layer on a substrate includes vaporizing a precursor by spraying atomizing gas to the precursor while a first external force is applied to the precursor during a first deposition sub-cycle to result in a first vaporized precursor, introducing the first vaporized precursor to a chamber in which the substrate is disposed during the first deposition sub-cycle, vaporizing the precursor by spraying the atomizing gas to the precursor while a second external force is applied to the precursor during a second deposition sub-cycle that follows the first deposition sub-cycle to result in a second vaporized precursor, and introducing the second vaporized precursor to the chamber in which the substrate remains disposed during the second deposition sub-cycle. The first external force may be greater than the second external force. In some embodiments, vaporizing the precursor during the first deposition sub-cycle includes spraying the atomizing gas toward the precursor while applying the first external force to the precursor, and vaporizing the precursor during the second deposition sub-cycle includes spraying the atomizing gas toward the precursor while applying the second external force to the precursor. In some embodiments, the first external force and the second external force are each applied to the precursor by an ultrasonic generator generating ultrasonic waves. The frequency of the ultrasonic waves generated by the ultrasonic generator during the first deposition sub-cycle may be 10 to 1000 times the frequency of the ultrasonic waves generated by the ultrasonic generator during the second deposition sub-cycle. In some embodiments, the first deposition sub-cycle is repeated at least two times prior to performing the second deposition sub-cycle, and the second deposition sub-cycle is performed one or more times after completion of the repeated first deposition sub-cycles. The repeated first deposition sub-cycles may be part of an atomic layer deposition process, and the one or more second deposition sub-cycles may be part of a chemical vapor deposition process. Each first deposition sub-cycle may include a first step of introducing the first vaporized precursor to the chamber, and a second later step of introducing a reactant to the chamber while not supplying the precursor to the chamber, and each second deposition sub-cycle may include a first step of introducing the second vaporized precursor to the chamber while simultaneously introducing the reactant to the chamber. In some embodiments, a smaller volume of precursor is introduced to the chamber during each first deposition sub-cycle than the volume of precursor introduced to the chamber during each second deposition sub-cycle. In addition, a first layer may be deposited during each first deposition sub-cycle and a second layer may be deposited during each second deposition sub-cycle, wherein a thickness of the layer deposited during each first deposition sub-cycle is less than a thickness of the layer deposited during each second deposition sub-cycle, and the same material is deposited during each first deposition sub-cycle as during each second deposition sub-cycle.

According to some embodiments, a method for depositing a material layer on a substrate includes placing the substrate in a chamber, performing an atomic layer deposition (ALD) process by alternately first supplying a precursor with a source gas to the chamber while not supplying a reactant to the chamber and second supplying the reactant to the chamber while not supplying the precursor or source gas, and subsequent to performing the ALD and without removing the substrate from the chamber, performing a chemical vapor deposition (CVD) process by third supplying the precursor with the source gas to the chamber while simultaneously supplying the reactant to the chamber. The combined ALD process and CVD process results in depositing the material layer on the substrate. The first supplying the precursor with the source gas during the ALD process may include vaporizing the precursor by spraying atomizing gas to the precursor while a first external force is applied to the precursor to result in a first vaporized precursor, and the third supplying the precursor with the source gas during the CVD process may include vaporizing the precursor by spraying the atomizing gas to the precursor while a second external force smaller than the first external force is applied to the precursor to result in a second vaporized precursor. In some embodiments, the first supplying the precursor with the source gas during the ALD process includes supplying the precursor with the source gas for a shorter period of time than the third supplying the precursor with the source gas during the CVD process. In some embodiments, the first external force and the second external force are each applied to the precursor by an ultrasonic generator generating ultrasonic waves. In some embodiments, the the frequency of the ultrasonic waves generated by the ultrasonic generator during the first supplying the precursor with the source gas during the ALD process may be 10 to 1000 times the frequency of the ultrasonic waves generated by the ultrasonic generator during the third supplying the precursor with the source gas during the CVD process. In some embodiments, a first flow regulator is provided on a supply line of a canister that supplies the precursor, wherein the first flow regulator is controlled to supply a first volume of precursor during the first supplying the precursor with the source gas during the ALD process, and is controlled to supply a second volume of precursor greater than the first volume during the third supplying the precursor with the source gas during the CVD process.

While the inventive concept has been particularly shown and described with reference to embodiments thereof, it will be understood that various changes in form and details may be made therein without departing from the spirit and scope of the following claims.

What is claimed is:

1. A substrate deposition apparatus configured to perform a deposition process on a substrate, the substrate deposition apparatus comprising:
a canister configured to discharge a precursor through a first supply line;
a vaporizer comprising a frame connected to the first supply line of the canister, a first atomization device configured to spray atomizing gas to the precursor introduced into an internal space of the frame, a second atomization device configured to apply an external force to the precursor introduced into the internal space of the frame, and a heating device configured to heat the precursor introduced into the internal space of the frame; and
a controller configured to control the second atomization device to switch between a high energy mode and a low energy mode in which different external forces are applied to the precursor introduced into the internal space of the frame, while performing the deposition process,
wherein an external force applied by the second atomization device to the precursor when the second atomization device is in the low energy mode is less than an external force applied by the second atomization device to the precursor when the second atomization device is in the high energy mode.

2. The substrate deposition apparatus of claim 1, wherein:
the second atomization device comprises an ultrasonic generator, and
a frequency of ultrasonic waves generated by the ultrasonic generator of the second atomization device in the high energy mode is greater than a frequency of ultrasonic waves generated by the ultrasonic generator of the second atomization device in the low energy mode.

3. The substrate deposition apparatus of claim 2, wherein the frequency of the ultrasonic waves of the second atomization device in the low energy mode is 40 kHz to 120 kHz.

4. The substrate deposition apparatus of claim 2, wherein a frequency of the ultrasonic waves of the second atomization device in the high energy mode is 10 to 1000 times the frequency of the ultrasonic waves of the second atomization device in the low energy mode.

5. The substrate deposition apparatus of claim 1, wherein the canister is configured to supply the precursor in a liquid state to the vaporizer.

6. The substrate deposition apparatus of claim 1, further comprising:
a first flow regulator provided on the first supply line of the canister and configured to regulate a supply amount of the precursor,
wherein:
the controller is configured to control the first flow regulator between a small-volume supply mode and a large-volume supply mode in which supply amounts of the precursor are different, while performing the deposition process, and
the supply amount of the precursor in the small-volume supply mode of the first flow regulator is less than the supply amount of the precursor in the large-volume supply mode of the first flow regulator.

7. The substrate deposition apparatus of claim 6, wherein the controller is configured to:
control the first flow regulator to be in the large-volume supply mode when the second atomization device is in the low energy mode, and
control the first flow regulator to be in the small-volume supply mode when the second atomization device is in the high energy mode.

8. A substrate deposition apparatus configured to perform a deposition process on a substrate, the deposition process comprising a first sub-cycle and a second sub-cycle performed after the first sub-cycle, the substrate deposition apparatus comprising:
a process chamber configured to receive the substrate for mounting in the process chamber;
a precursor supply unit configured to supply a precursor to the process chamber;
a reactant supply unit configured to supply a reactant to the process chamber;
a purge supply unit configured to supply a purge gas to the process chamber; and
a controller configured to control a supply amount of the precursor of the precursor supply unit, a supply amount of the reactant of the reactant supply unit, and a supply amount of the purge gas of the purge supply unit,
wherein:
the precursor supply unit comprises:
a canister configured to discharge the precursor through a first supply line; and
a vaporizer comprising a frame connected to the first supply line of the canister, a first atomization device configured to spray atomizing gas to the precursor introduced into an internal space of the frame, a second atomization device configured to apply an external force to the precursor introduced into the internal space of the frame, and a heating device configured to heat the precursor introduced into the internal space of the frame,
the controller is configured to control the second atomization device between a high energy mode and a low energy mode in which different external forces are applied to the precursor introduced into the internal space of the frame by the second atomization device, while performing the deposition process, and
an external force applied by the second atomization device to the precursor when the second atomization device is in the low energy mode is less than an external force applied by the second atomization device to the precursor when the second atomization device is in the high energy mode.

9. The substrate deposition apparatus of claim 8, wherein the controller is configured to, while the substrate deposition apparatus is performing the first sub-cycle, control the second atomization device to switch from the high energy mode to a stop mode in which the second atomization device does not operate.

10. The substrate deposition apparatus of claim 9, wherein the controller is configured to, when the second atomization device is in the high energy mode, control the reactant supply unit so that the reactant is not supplied to the process chamber, and control the purge supply unit so that the purge gas is not supplied to the process chamber.

11. The substrate deposition apparatus of claim 9, wherein the controller is configured to, while the substrate deposition apparatus is performing the second sub-cycle, control the second atomization device to switch from the high energy mode to the stop mode.

12. The substrate deposition apparatus of claim 11, wherein, the controller is configured to, when the second atomization device is in the low energy mode control the purge supply unit so that the reactant is supplied to the process chamber, and control the purge supply unit so that the purge gas is not supplied to the process chamber.

13. The substrate deposition apparatus of claim 11, wherein a time taken for the controller to maintain the second atomization device in the high energy mode is less than a time taken for the controller to maintain the second atomization device in the low energy mode.

14. The substrate deposition apparatus of claim 11, wherein the controller is configured to:
when the second atomization device is in the high energy mode, control the canister to supply the precursor to the vaporizer at a first flow rate, and
when the second atomization device is in the low energy mode, control the canister to supply the precursor to the vaporizer at a second flow rate that is greater than the first flow rate.

15. The substrate deposition apparatus of claim 14, wherein the controller is configured to, when the canister supplies the precursor to the vaporizer, control the first atomization device to spray the atomizing gas to the precursor introduced into the internal space of the frame of the vaporizer.

16. The substrate deposition apparatus of claim 8, wherein:
the precursor supply unit further comprises a second supply line connecting the vaporizer to the process chamber and a first flow regulator provided on the first supply line and configured to regulate a flow rate of the precursor passing through the first supply line,
the second atomization device of the vaporizer of the precursor supply unit comprises an ultrasonic generator, and
the canister of the precursor supply unit comprises a direct liquid injection (DLI) canister.

17. The substrate deposition apparatus of claim 16, wherein a frequency of ultrasonic waves generated by the ultrasonic generator of the second atomization device in the high energy mode is 10 to 1000 times a frequency of ultrasonic waves generated by the ultrasonic generator of the second atomization device in the low energy mode.

18. A substrate deposition apparatus configured to perform a deposition process on a substrate, the substrate deposition apparatus comprising:
a process chamber configured to receive a substrate for mounting in the process chamber;
a precursor supply unit configured to supply a precursor to the process chamber;
a reactant supply unit configured to supply a reactant to the process chamber;
a purge supply unit configured to supply a purge gas to the process chamber; and
a controller configured to control a supply amount of the precursor of the precursor supply unit, a supply amount of the reactant of the reactant supply unit, and a supply amount of the purge gas of the purge supply unit,
wherein:
the precursor supply unit comprises:
a canister configured to discharge the precursor in a liquid state through a first supply line; and
a vaporizer comprising a frame connected to the first supply line of the canister, a first atomization device configured to spray atomizing gas to the precursor introduced into an internal space of the frame, a second atomization device comprising an ultrasonic generator for applying ultrasonic waves to the precursor introduced into the internal space of the frame, and a heating device configured to heat the precursor introduced into the internal space of the frame,
the second atomization device comprises a low energy mode in which a frequency of ultrasonic waves generated by the ultrasonic generator is a first frequency and a high energy mode in which the frequency of the ultrasonic waves is a second frequency that is greater than the first frequency, and
the controller is configured to switch the second atomization device between the low energy mode and the high energy mode while performing the deposition process.

19. The substrate deposition apparatus of claim 18, wherein:
when the second atomization device is in the low energy mode, the frequency of the ultrasonic waves generated by the ultrasonic generator of the second atomization device is 40 kHz to 120 kHz, and
when the second atomization device is in the high energy mode, the frequency of the ultrasonic waves generated by the ultrasonic generator of the second atomization device is 10 to 1000 times the frequency of the ultrasonic waves generated by the ultrasonic generator of the second atomization device in the low energy mode.

20. The substrate deposition apparatus of claim 18, wherein the controller is configured to:
when the second atomization device is in the high energy mode, control the canister to supply the precursor to the vaporizer at a first flow rate, and
when the second atomization device is in the low energy mode, control the canister to supply the precursor to the vaporizer at a second flow rate that is greater than the first flow rate.
